(19) United States
(12) Patent Application Publication
(10) Pub. No.: US 2025/0192523 A1
(43) Pub. Date: Jun. 12, 2025

(54) CO-LINEAR PHASE DETECTION SYSTEM FOR COHERENT BEAM COMBINING

(71) Applicant: Lumentum Operations LLC, San Jose, CA (US)

(72) Inventors: Benedikt HERMANN, Schlieren (CH); Simonette PIERROT, Zurich (CH)

(21) Appl. No.: 18/581,789

(22) Filed: Feb. 20, 2024

Related U.S. Application Data
(60) Provisional application No. 63/608,614, filed on Dec. 11, 2023.

(51) Int. Cl. H01S 5/40; G01J 9/00; H01S 5/068; H01S 5/0683

(52) U.S. Cl. CPC H01S 5/4012; G01J 9/00; H01S 5/06821; H01S 5/0683

(57) ABSTRACT

In some implementations, a phase detector to enable coherent beam combining includes a first half-waveplate may rotate a polarization of a first input beam and a second input beam to 45 degrees. A first birefringent window may divide the input beams into beamlet pairs associated with orthogonal polarizations, and a second birefringent window may shift the first beamlet pair and the second beamlet pair such that a first beamlet of the first beamlet pair and a second beamlet of the second beamlet pair form overlapping beams after the orthogonal polarizations and reversed by a second half-waveplate. An analyzer may then split the overlapping beams into a first output beam associated with a first intensity and a second output beam associated with a second intensity, where a difference between the first and second intensity is related to a phase difference between the first input beam and the second input beam.

### CROSS-REFERENCE TO RELATED APPLICATION

This patent application claims priority to U.S. Provisional Patent Application No. 63/608,614, filed on Dec. 11, 2023, and entitled “PHASE DETECTION TECHNIQUES FOR COHERENT BEAM COMBINING.” The disclosure of the prior application is considered part of and is incorporated by reference into this patent application.

### TECHNICAL FIELD

The present disclosure relates generally to coherent beam combining and to a co-linear phase detector that may detect phase errors within an array of co-propagating beams.

### BACKGROUND

Coherent beam combining (CBC) is a technique used in optics to merge multiple laser beams into a single output beam with higher power and/or a desired beam quality. CBC is particularly useful in applications where the power of a single laser is insufficient, and scaling the power of a single emitter is challenging due to physical and/or technological limitations. The fundamental principle of CBC involves the superposition of individual laser beams in a manner that results in constructive interference, which in turn increases in the intensity of the combined beam. To achieve the increase in intensity, the phase and amplitude of each individual laser beam needs to be carefully controlled. For example, the phase and/or amplitude control may be accomplished through active and/or passive phase-locking mechanisms, which can include electronic feedback systems that adjust the phases of the lasers in real-time based on the observed interference pattern of the beams. The implementation of CBC can be categorized into two main architectures: tiled-aperture combining and filled-aperture combining. In tiled-aperture combining, individual laser beams are arranged in a two-dimensional array, and phases of the laser beams are controlled to constructively interfere at a distant target, effectively creating a single high-power beam. The tiled-aperture approach is beneficial in high-power laser systems, such as those used in directed energy applications. Filled-aperture combining involves overlapping the beams in the same spatial mode of a single aperture, which is advantageous for applications requiring high beam quality and brightness, such as in fiber laser systems. However, CBC poses challenges, including the need for precise phase control to maintain coherence and the complexity of scaling the system with a large number of emitters.

### SUMMARY

In some implementations, a phase detector includes a first half-waveplate (HWP) arranged to receive a first input beam and a second input beam that are co-propagating with a first polarization, and to rotate the first polarization to 45 degrees (°); a first birefringent window, arranged after the first HWP, to divide the first input beam into a first beamlet pair associated with orthogonal polarizations, and to divide the second input beam into a second beamlet pair associated with orthogonal polarizations; a second HWP, arranged after the first birefringent window, to reverse the orthogonal polarizations associated with the first beamlet pair and the second beamlet pair; a second birefringent window, arranged after the second HWP, to refract and shift the first beamlet pair and the second beamlet pair such that a first beamlet of the first beamlet pair and a second beamlet of the second beamlet pair form overlapping beams; and an analyzer, arranged after the second birefringent window, to split the overlapping beams into a first output beam associated with a first intensity and a second output beam associated with a second intensity, wherein a difference between the first intensity and the second intensity is related to a phase difference between the first input beam and the second input beam.

In some implementations, a method for phase detection to enable coherent beam combining includes receiving, by a phase detector that comprises a plurality of optical devices arranged in a linear optical path, a first input beam and a second input beam; dividing, by the phase detector, the first input beam into a first beamlet pair associated with orthogonal polarizations and the second input beam into a second beamlet pair associated with orthogonal polarizations; shifting, by the phase detector, the first beamlet pair and the second beamlet pair such that a first beamlet of the first beamlet pair and a second beamlet of the second beamlet pair form overlapping beams; and splitting, by the phase detector, the overlapping beams into a first output beam associated with a first intensity and a second output beam associated with a second intensity, wherein a difference between the first intensity and the second intensity is related to a phase difference between the first input beam and the second input beam.

In some implementations, an optical system includes a laser source configured to generate a seed laser; a division stage comprising one or more optical devices configured to divide the seed laser into a beam array that comprises a first input beam and a second input beam that co-propagate with a first polarization; an amplification stage comprising a first amplifier to amplify the first input beam and a second amplifier to amplify the second input beam; a combination stage comprising one or more optical devices configured to combine the amplified first input beam and the amplified second input beam to generate an output beam; a phase detector, provided after the amplification stage, comprising: a first HWP arranged to receive the first input beam and the second input beam and to rotate the first polarization to 45°; a first birefringent window, arranged after the first HWP, to divide the first input beam into a first beamlet pair associated with orthogonal polarizations and to divide the second input beam into a second beamlet pair associated with orthogonal polarizations; a second HWP, arranged after the first birefringent window, to reverse the orthogonal polarizations associated with the first beamlet pair and the second beamlet pair; a second birefringent window, arranged after the second HWP, to refract and shift the first beamlet pair and the second beamlet pair such that a first beamlet of the first beamlet pair and a second beamlet of the second beamlet pair form overlapping beams; and an analyzer, arranged after the second birefringent window, to split the overlapping beams into a first output beam associated with a first intensity and a second output beam associated with a second intensity, wherein a difference between the first intensity and the second intensity is related to a phase difference between the first input beam and the second input beam; and a feedback loop that comprises one or more devices configured to measure the first intensity and the second intensity and to generate a control signal to modulate, prior to the amplification stage, a phase of one or more of the first input beam or the second input beam according to the phase difference between the first input beam and the second input beam.

### BRIEF DESCRIPTION OF THE DRAWINGS

FIG. 1 is a diagram illustrating an example of a Hänsch-Couillaud phase detection system that may be used in a coherent beam combining system.

FIG. 2 is a diagram illustrating an example implementation associated with a co-linear phase detector that may be used in a coherent beam combining system described herein.

FIG. 3 is a diagram illustrating an example implementation of a coherent beam combining system that includes the co-linear phase detector described herein.

FIG. 4 is a flowchart illustrating an example process performed, for example, by a co-linear phase detector in a coherent beam combining system.

### DETAILED DESCRIPTION

The following detailed description of example implementations refers to the accompanying drawings. The same reference numbers in different drawings may identify the same or similar elements.

Fiber laser technology has many properties that are useful for various light-induced applications in science, industry, and other fields. For example, fiber laser systems have characteristics that enable power scaling, excellent beam quality and stability, high quantum efficiency, wide gain bandwidth, and/or thermal management, which has resulted in fiber laser systems often being used for versatile laser sources in continuous wave (CW) and pulsed regimes. For example, because fiber laser systems enable power scaling, fiber laser systems are often used in applications that demand high power levels (e.g., in a kilowatt (kW) regime), such as advanced material processing and laser particle accelerators, among other examples. For example, fiber laser systems using high-brightness laser diodes and double-cladding fibers can offer significantly higher output powers than fiber laser systems that pump through single-clad fibers, and chirped pulse amplification techniques enable further power scaling for ultrafast (e.g., femtosecond) pulses in single amplification channels (e.g., single core amplifiers).

However, ultrafast fiber laser technology is approaching a power scaling limit of single core amplifiers due to various physical limitations, which include nonlinear effects, polarization losses, mode instabilities, thermal issues, optical damage, and/or pump power limitations. Accordingly, in some cases, beam combining techniques may be used to enable further power scaling in a fiber laser system. For example, beam combining techniques may use several fibers or several cores to split a seed laser beam before an amplification stage to distribute the intensity of the beam over the several fibers or several cores, and then the split beams are individually amplified and combined into a single output. In general, the amplification can be performed using multiple amplifier channels, which can be individual fibers or a multicore fiber (MCF) where multiple cores are embedded within a single larger fiber and the beams are amplified in parallel before being recombined. However, in order to combine the multiple individual lasers in an efficient manner, phase control for the individual beamlets is essential.

Accordingly, coherent beam combining (CBC) techniques may be used to (re) combine multiple beams more efficiently. For example, in a CBC system, power scaling may be achieved by combining multiple laser amplifiers that are seeded by common laser source into a single high-power output beam while maintaining beam quality and preserving spatial and spectral properties of the lasers. For example, in a CBC system, there is a phase relation between the multiple laser amplifiers, with parallel amplifiers effectively operating as a single laser. The general notion is that a seed beam is split into several replicas (e.g., N channels) that are then amplified to the highest possible power and/or energy through the parallel amplifier sections, and the amplified replicas of the seed beam are then combined into a single beam. To maximize the combining efficiency and avoid intensity fluctuations, temporal delays (e.g., phase differences) between beamlets in different cores or different fibers need to be stabilized down to a fraction of a wavelength. For example, a CBC system may use active phase control, where a phase detector is used at an output side of the amplifier stage to detect phase differences between neighboring beams and a phase modulator is used (e.g., prior to or after the amplification stage) to correct the phase differences that are detected using the phase detector. However, actuator schemes that are typically used for phase control suffer from various drawbacks.

For example, actuator schemes that are commonly used for phase control include piezoelectric arrays and/or liquid phase masks, among other examples. In one phase control technique, photo diodes after a combining element may be used for phase optimization and stabilization, and a heterodyne dithering scheme operating at radio frequencies is used to modulate the phase of each core at a slightly different frequency. The resulting signals on the photo diodes may then be analyzed to yield mutual phase differences. Another approach with a single photodiode uses an optimization algorithm called stochastic parallel gradient descent (SPGD), which is an iterative method and therefore slower than any direct phase measurement technique (e.g., fast phase fluctuations are not correctable). Alternatively, mutual phase differences may be measured with a Hänsch-Couillaud detector (HCD) for each pair of combining beams. In this approach, interference distributes the signal to two ports depending on the mutual phase.

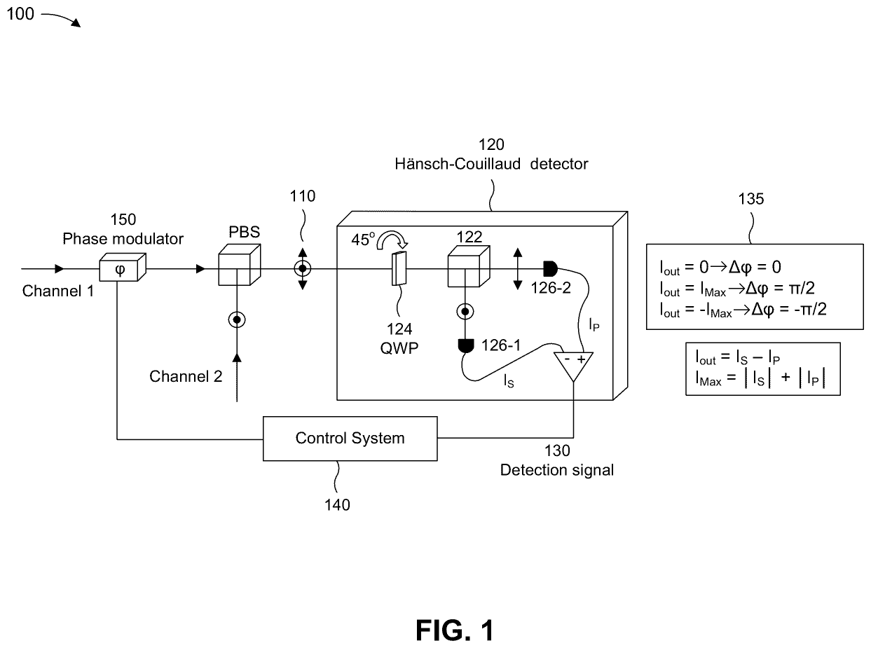

For example, FIG. 1 is a diagram illustrating an example 100 of a Hänsch-Couillaud phase detection system that may be used for CBC of two channels. For polarization beam combining, Hänsch-Couillaud polarization detection is often used to measure a phase difference between two orthogonal beams. For example, as shown by reference number 110 in FIG. 1, a small fraction of a combined laser beam may be directed to an HCD 120, which includes one polarization beam splitter (PBS) 122, one quarter-wave plate (QWP) 124, and two photodiodes 126-1 and 126-2. There is a 45° difference between the axis of the QWP 124 and the axis of the PBS 122, which leads to a split into two laser beams with orthogonal polarization. The two photodiodes 126-1 and 126-2 are located in different output ports of the PBS 122, and are used to measure the optical beam powers and create electrical signals representing the respective optical beam powers, which are used to calculate a detection signal 130 based on a difference between the optical beam powers. For example, as shown in FIG. 1, a first photodiode 126-1 produces a first electrical signal, Is, representing the optical beam power from a first output port of the PBS 122, and a second photodiode 126-2 produces a second electrical signal, Ip, representing the optical beam power from a second output port of the PBS 122. Accordingly, as shown by reference number 135, the detection signal 130, Iout, may be calculated by determining the difference between the first electrical signal and the second electrical signal (e.g., Is−Ip), where a maximum difference between the first electrical signal and the second electrical signal, Imax, is based on the sum of the absolute value of Is and the absolute value of Ip. As further shown by reference number 135, when the detection signal 130 has a value of 0, the phase between the two optical beams is 0. Alternatively, the phase between the two optical beams is π/2 when the detection signal 130 has a value of Imax or negative ½ when the detection signal 130 has a value of negative Imax. Therefore, using the Hänsch-Couillaud approach, the phase difference between the two optical signals is indicated by the detection signal 130, which is provided to a control system 140 that then controls a phase modulator 150 to adjust the phase of one or more of the two optical beams based on their phase difference.

In an ideal CBC of two orthogonal polarized beams with the same power and phase, the combined beam is completely linear polarized, rotated by 45° compared to the initial input beams. If a sample of the combined beam is directed toward the HCD 120, the QWP 124, which is rotated 45° relative to the axis of the PBS 122, creates a circular polarization beam. The PBS 122 then divides the circular polarization beam into two orthogonal polarized beams with the same optical power. In this state, the detection signal 130 may be zero, which indicates perfect co-phasing between the channels. In this way, the HCD 120 approach offers a direct, single-shot technique to control phases (e.g., a feedback bandwidth up to a pulse repetition rate is potentially achievable). In addition, the HCD 120 may be parallelized for multiple co-propagating beams. However, the HCD technique suffers from various drawbacks. For example, the HCD 120 requires beam splitters, wave plates, and mirrors, and requires accurate alignment for each pair of recombining beamlets. The use of beam splitters may require a precise transverse alignment to ensure spatial overlap and path length matching for pulsed lasers to ensure temporal overlap. Moreover, the use of polarization beam splitters (e.g., PBS 122) requires that each pair of beams be sent to each PBS with a 90° angle, which occupies significant space. Accordingly, some implementations described in further detail herein relate to a phase detector that uses waveplates and birefringent windows to enable mirror-free phase detection in a co-linear arrangement (e.g., in contrast to a Hänsch-Couillaud design that uses polarizing beam splitters and mirrors to overlap and split the beams). In this way, some implementations described herein may provide a compact and simple phase detector (e.g., occupying less space than an HCD) that can directly detect phase errors within an array of co-propagating beams to correct phase differences that may otherwise lead to a loss of combining efficiency and/or output energy fluctuations.

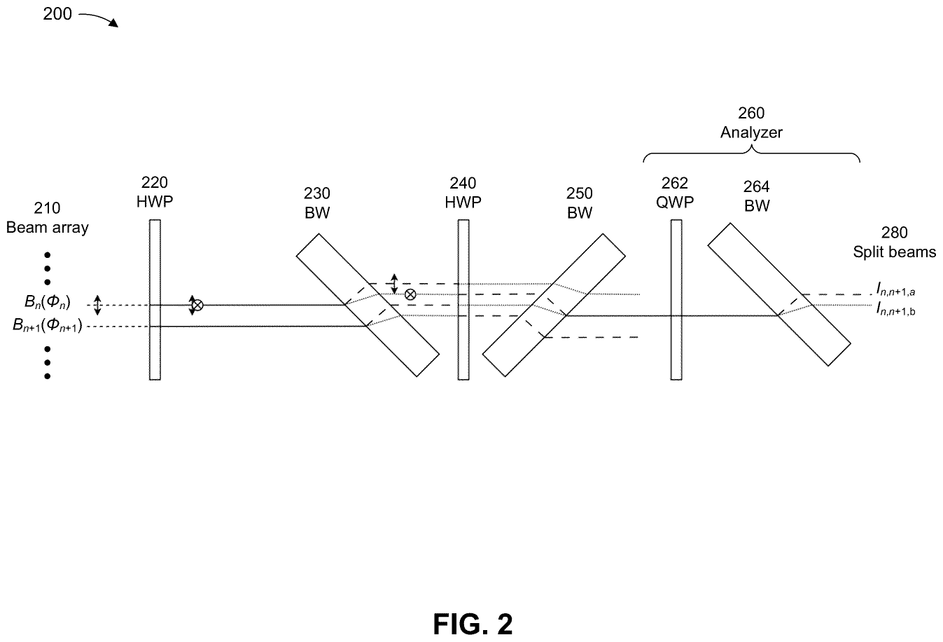

FIG. 2 is a diagram illustrating an example implementation associated with a co-linear phase detector 200 that may be used in a coherent beam combining system described herein. As described herein, the co-linear phase detector 200 may enable compact, simple, and direct detection of phase errors within a beam array 210 including multiple beams that are co-propagating in parallel, as phase differences between the beams in the beam array 210 may otherwise lead to loss of combining efficiency and/or output energy fluctuations. For example, in some implementations, the co-linear phase detector 200 provides an alignment-free optical arrangement to directly detect phase variations within the beam array 210. For example, in contrast to a Hänsch-Couillaud configuration with polarizing beam splitters (e.g., as shown in FIG. 1), the co-linear phase detector 200 includes various optical devices that are arranged in a linear optical path. Accordingly, the co-linear phase detector 200 is more compact does not require folding mirrors to overlap individual beams, which significantly simplifies an alignment procedure.

For example, as shown in FIG. 2, the beam array 210 includes multiple beams (beam B₀, B₁, . . . , B_{N}) that are co-propagating in parallel with a particular polarization, where each beam Bᵢ is associated with a corresponding phase, Φᵢ. For example, as shown in FIG. 2, a first beam Bₙ is associated with a first phase, Φₙ, a second beam Bₙ₊₁ is associated with a second phase, Φₙ₊₁, and so on. Furthermore, in FIG. 2, dashed lines indicate a horizontal polarization, dotted lines indicate a vertical polarization, and solid lines indicate a superposition of horizontal and vertical polarizations. Accordingly, in some implementations (e.g., as shown in FIG. 2), the parallel beams in the beam array 210 may be co-propagating with a horizontal polarization. Alternatively, in some implementations, the beams in the beam array 210 may co-propagate with a vertical polarization or another suitable linear polarization. Furthermore, although FIG. 2 illustrates a scenario where the co-linear phase detector 200 is used to determine the phase difference between two input beams, the beam array 210 may include more than two beams and the co-linear phase detector 200 can suitably measure a phase difference between any two adjacent beams in the beam array 210. Furthermore, the co-linear phase detector 200 can be used to measure phase differences between two non-adjacent beams in the beam array 210 (e.g., a phase difference between beam Bₙ and beam Bₙ₊₂ may be determined based on a first phase difference between beam Bₙ and beam Bₙ₊₁ and a second phase difference between beam Bₙ₊₁ and beam Bₙ₊₂).

As further shown in FIG. 2, the co-linear phase detector 200 includes a first HWP 220. In some implementations, the first input beam Bₙ and the second input beam Bₙ₊₁ are received at the first HWP 220, which may be oriented at a particular angle, θ, relative to a propagation axis of the co-propagating beams in the beam array 210, such that the first HWP 220 rotates the polarization of the first input beam Bₙ and the second input beam Bₙ₊₁ to 20. For example, in some implementations, the first HWP 220 may be oriented at a 22.5° angle relative to the propagation axis of the beams in the beam array 210, whereby the first HWP 220 rotates the polarization of the first input beam Bₙ and the second input beam Bₙ₊₁ to 45°.

As further shown in FIG. 2, the co-linear phase detector 200 includes a first birefringent window 230, arranged after the first HWP 220, to divide or split the first input beam Bₙ into a first beamlet pair associated with orthogonal polarizations, and to divide or split the second input beam Bₙ₊₁ into a second beamlet pair associated with orthogonal polarizations. For example, as shown in FIG. 2, the first birefringent window 230 splits each input beam into a beamlet pair that includes a first beamlet with a horizontal polarization (shown by dashed lines) and a second beamlet with a vertical polarization (shown by dotted lines). The first birefringent window 230 may be made from any suitable birefringent material, such as alpha-barium borate (alpha-BBO, α-BaB2O4, or α-BBO) birefringent crystal, undoped vanadate, calcite, and/or rutile, among other examples. The first birefringent window 230 may refract orthogonal polarizations (e.g., ordinary and extraordinary polarizations) at different angles due to the first birefringent window 230 having birefringence (e.g., a refractive index that depends on the polarization and propagation direction of input light). As shown in FIG. 2, the two copies of each beam (e.g., each beamlet pair) exit the first birefringent window 230 shifted in a lateral direction (e.g., shown by a vertical arrow). For example, the incoming beams enter the first birefringent window 230 and the outgoing beams exit the first birefringent window 230 with the same propagation direction, with the respective propagation axes shifted laterally. Furthermore, in some implementations, the first birefringent window 230 may have a thickness and/or an angle that is based on a separation between the input beams. For example, the first birefringent window 230 may have a thickness and/or an angle that results in the first birefringent window 230 laterally shifting the propagation axes of the two copies of each beam by half the incoming beam separation. Furthermore, the angle of the first birefringent window 230 may be matched to avoid introducing additional phases.

As further shown in FIG. 2, the co-linear phase detector 200 includes a second HWP 240, arranged after the first birefringent window 230, to reverse the orthogonal polarizations associated with the first beamlet pair and the second beamlet pair (e.g., the second HWP 240 reverses the polarization of each beamlet). For example, in FIG. 2, the first birefringent window 230 splits the first input beam Bₙ and the second input beam Bₙ₊₁ into two respective beamlet pairs that each include a first beamlet with a horizontal polarization (shown by dashed lines) and a second beamlet with a vertical polarization (shown by dotted lines). Accordingly, the second HWP 240 may be oriented at 45° to reverse the polarization of each beamlet, such that each beamlet that enters the second HWP 240 with a horizontal polarization exits the second HWP 240 with a vertical polarization. Similarly, each beamlet that enters the second HWP 240 with a vertical polarization exits the second HWP 240 with a horizontal polarization.

As further shown in FIG. 2, the co-linear phase detector 200 includes a second birefringent window 250, arranged after the second HWP 240, to refract and shift the first beamlet pair and the second beamlet pair such that a first beamlet of the first beamlet pair and a second beamlet of the second beamlet pair form overlapping beams. For example, in FIG. 2, the two beamlet pairs entering the second birefringent window 250 include a first beamlet pair, associated with the first input beam Bₙ, and a second beamlet pair, associated with the second input beam Bₙ₊₁. As shown, the first beamlet pair includes a beamlet with a horizontal polarization and the second beamlet pair includes a beamlet with a vertical polarization, where the refraction and lateral shift that occurs in the second birefringent window 250 results in the horizontally polarized beamlet of the first beamlet pair and the vertically polarized beamlet of the second beamlet pair forming an overlapping beam upon exiting the second birefringent window 250. In some implementations, the second birefringent window 250 may be made from any suitable birefringent material (e.g., a-BBO birefringent crystal, undoped vanadate, calcite, and/or rutile), which may be the same as or different from the birefringent material used for the first birefringent window 230. Furthermore, the second birefringent window 250 may also have a thickness and/or an angle that is based on a separation between the input beams (e.g., the second birefringent window 250 may have a thickness and/or an angle that results in the second birefringent window 250 laterally shifting each beam by half the incoming beam separation).

As further shown in FIG. 2, the co-linear phase detector 200 includes an analyzer 260, arranged after the second birefringent window 250, to split the overlapping beams into a first output beam associated with a first intensity and a second output beam associated with a second intensity. For example, as shown in FIG. 2, the analyzer may comprise a QWP 262 arranged after the second birefringent window 250 and a third birefringent window 264 arranged after the QWP 262. In some implementations, the third birefringent window 264 may be made from any suitable birefringent material, which may be the same as or different from the birefringent material used for the first birefringent window 230 and/or the second birefringent window 230. In some implementations, one or more of the first birefringent window 230 may be anti-reflection coated (e.g., to ensure better transmission and avoid ghosting where additional beam copies are created by multiple reflections). In some implementations, the QWP 262 may transform the polarization state of the overlapping beams, which is a function of the phase difference between the two input beams, into a polarization state that can then be split by the third birefringent window 264. For example, the third birefringent window 264 may split the polarization state of the overlapping beams according to a splitting ratio that depends on a polarization ratio (e.g., removing the QWP 262 from the co-linear arrangement would result in the splitting ratio always being 1:1). For example, in some implementations, the QWP 262 may transform a left-hand circular input polarization to a horizontal output polarization, a right-hand circular input polarization to a vertical output polarization, and/or a linear input polarization at 45° to a linear output polarization at 45° (unchanged). Accordingly, depending on the input phase, the beam entering the QWP 262 is linearly polarized at 45° (corresponding to an input phase zero), circularly polarized (e.g., left-handed or right-handed for an input phase ±π), or elliptically polarized, and the third birefringent window 264 then splits the overlapping beams to generate a set of split beams 280. Accordingly, an intensity difference between the split beams 280 is related to the initial phase difference by the following formula:

$${I}_{n , n + 1 , a} - {I}_{n , n + 1 , b} = sin ( {∅}_{n} - {∅}_{n + 1} )$$

where I_{n,n+1,a} and I_{n,n+1,b} are the intensities of the respective beams and a difference between the intensities is approximately equal to a sine of the phase difference between the first input beam Bₙ and the second input beam Bₙ₊₁. In general, the intensities are equal only when the phase difference between the first input beam Bₙ and the second input beam Bₙ₊₁ is zero. In this way, a feedback loop may include one or more devices (e.g., a camera or photodiode array sensitive at the laser wavelength) to measure the intensities, such that the feedback loop acting on the phase control can stabilize a phase within the beam array 210. For example, the feedback loop may include one or more devices or components that can generate a control signal to modulate a phase of one or more of the first input beam Bₙ or the second input beam Bₙ₊₁ according to the phase difference between the first input beam Bₙ and the second input beam Bₙ₊₁ to enable coherent combining of the various beams in the beam array 210. Furthermore, for a two-dimensional beam array, a second instance of the co-linear phase detector 200 may be rotated 90° and added to the co-linear phase detector 200 depicted in FIG. 2.

FIG. 2 is provided as an example. Other examples may differ from what is described with regard to FIG. 2. The number and arrangement of devices shown in FIG. 2 are provided as examples. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices. Additionally, or alternatively, a set of devices shown in FIG. 2 may perform one or more functions described as being performed by another set of devices shown in FIG. 2.

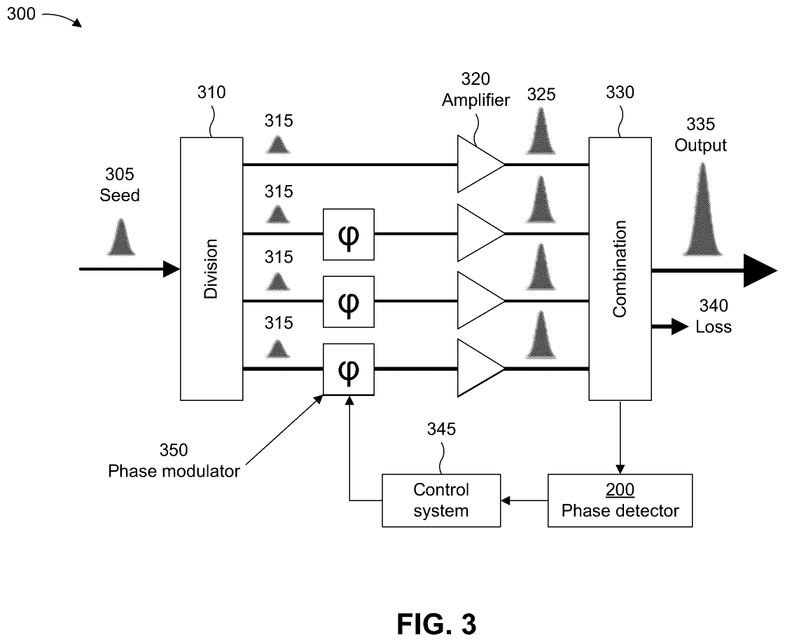

FIG. 3 is a diagram illustrating an example implementation of a coherent beam combining system 300 that includes the co-linear phase detector 200 described herein.

For example, in some implementations, the coherent beam combining system 300 may include or may be coupled to a laser source configured to generate a seed laser 305. As shown in FIG. 3, the coherent beam combining system 300 includes a division stage 310 comprising one or more optical devices configured to divide the seed laser 305 into a beam array 315 that comprises various input beams that co-propagate in parallel with a particular polarization (e.g., horizontal or vertical). As further shown in FIG. 3, the coherent beam combining system includes an amplification stage 320, which comprises multiple amplifiers that are each arranged to amplify an individual input beam in the beam array to form a set of amplified beams 325. As further shown, the coherent beam combining system 300 includes a combination stage comprising one or more optical devices configured to combine the amplified beams 325 into a single output beam 335. In addition, as shown, there may be a loss 340 of energy or power after the combination stage 330 (e.g., due to phase differences between the various beams in the beam array 315). Accordingly, as shown in FIG. 3, the co-linear phase detector 200 may be provided after the amplification stage 320 to measure phase differences between the beams in the beam array 315, as described in more detail above with respect to FIG. 2. In particular, the co-linear phase detector 200 may generate one or more signals that indicate the phase differences between the beams in the beam array 315. As shown in FIG. 3, the signal(s) indicating the phase differences between the beams in the beam array 315 may be provided to a control system 345, which may actuate or otherwise control one or more phase modulators 350 to stabilize the phases of the various beams in the beam array 315 and thereby minimize the loss 340.

FIG. 3 is provided as an example. Other examples may differ from what is described with regard to FIG. 3. The number and arrangement of devices shown in FIG. 3 are provided as examples. In practice, there may be additional devices, fewer devices, different devices, or differently arranged devices than those shown in FIG. 3. Furthermore, two or more devices shown in FIG. 3 may be implemented within a single device, or a single device shown in FIG. 3 may be implemented as multiple, distributed devices. Additionally, or alternatively, a set of devices shown in FIG. 3 may perform one or more functions described as being performed by another set of devices shown in FIG. 3.

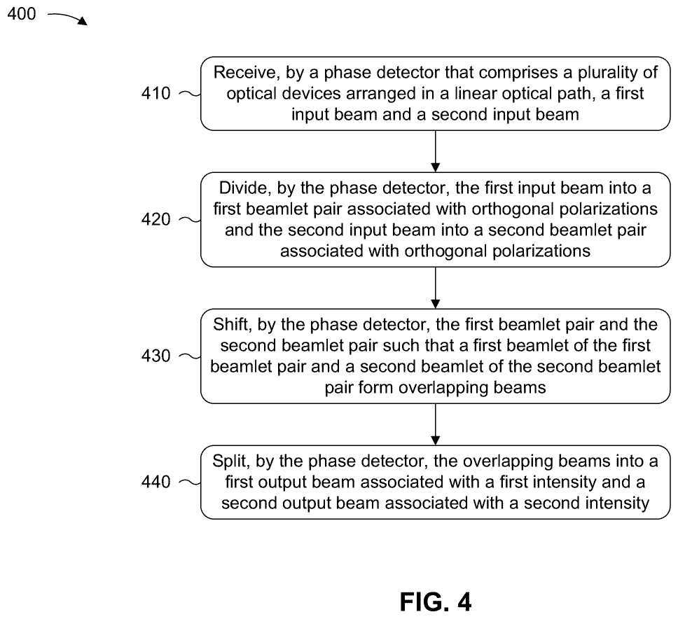

FIG. 4 is a flowchart of an example process 400 associated with phase detection in a coherent beam combining system. In some implementations, one or more process blocks of FIG. 4 are performed by a phase detector (e.g., phase detector 200). In some implementations, one or more process blocks of FIG. 4 are performed by another device or a group of devices separate from or including the phase detector, such as a laser source, a division stage, an amplification stage, a combination stage, and/or a control system in a coherent beam combining system.

As shown in FIG. 4, process 400 may include receiving a first input beam and a second input beam (block 410). For example, the first input beam and the second input beam may be received at a phase detector 200 that comprises a plurality of optical devices arranged in a linear optical path, as described above.

As further shown in FIG. 4, process 400 may include dividing the first input beam into a first beamlet pair associated with orthogonal polarizations and the second input beam into a second beamlet pair associated with orthogonal polarizations (block 420). For example, the phase detector 200 may divide the first input beam into a first beamlet pair associated with orthogonal polarizations and the second input beam into a second beamlet pair associated with orthogonal polarizations, as described above.

As further shown in FIG. 4, process 400 may include shifting the first beamlet pair and the second beamlet pair such that a first beamlet of the first beamlet pair and a second beamlet of the second beamlet pair form overlapping beams (block 430). For example, the phase detector 200 may shift the first beamlet pair and the second beamlet pair such that a first beamlet of the first beamlet pair and a second beamlet of the second beamlet pair form overlapping beams, as described above.

As further shown in FIG. 4, process 400 may include splitting the overlapping beams into a first output beam associated with a first intensity and a second output beam associated with a second intensity, wherein a difference between the first intensity and the second intensity is related to a phase difference between the first input beam and the second input beam (block 440). For example, the phase detector 200 may split the overlapping beams into a first output beam associated with a first intensity and a second output beam associated with a second intensity, wherein a difference between the first intensity and the second intensity is related to a phase difference between the first input beam and the second input beam, as described above.

Process 400 may include additional implementations, such as any single implementation or any combination of implementations described below and/or in connection with one or more other processes described elsewhere herein.

In a first implementation, process 400 includes providing a signal indicating the phase difference between the first input beam and the second input beam to a control system 345 configured to modulate one or more of a first phase of the first input beam or a second phase of the second input beam according to the phase difference.

In a second implementation, alone or in combination with the first implementation, the first input beam and the second input beam are received at a first HWP 220 configured to rotate a polarization of the first input beam and the second input beam to 45°.

In a third implementation, alone or in combination with one or more of the first and second implementations, the first input beam and the second input beam are divided into the first beamlet pair and the second beamlet pair by a first birefringent window 230, arranged after the first HWP 220.

In a fourth implementation, alone or in combination with one or more of the first through third implementations, process 400 includes reversing, by a second HWP 240, arranged after the first birefringent window 230, the orthogonal polarizations associated with the first beamlet pair and the second beamlet pair.

In a fifth implementation, alone or in combination with one or more of the first through fourth implementations, the first beamlet pair and the second beamlet pair are shifted by a second birefringent window 250, arranged after the second HWP 240.

In a sixth implementation, alone or in combination with one or more of the first through fifth implementations, the overlapping beams are split into the first output beam and the second output beam by an analyzer 260 that comprises a QWP 262, arranged after the second birefringent window 250, and a third birefringent window 264, arranged after the quarter-waveplate 262.

In a seventh implementation, alone or in combination with one or more of the first through sixth implementations, the difference between the first intensity and the second intensity is approximately equal to a sine of the phase difference between the first input beam and the second input beam.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A phase detector, comprising:
a first half-waveplate arranged to receive a first input beam and a second input beam that are co-propagating with a first polarization, and to rotate the first polarization to 45 degrees;
a first birefringent window, arranged after the first half-waveplate, to divide the first input beam into a first beamlet pair associated with orthogonal polarizations, and to divide the second input beam into a second beamlet pair associated with orthogonal polarizations;
a second half-waveplate, arranged after the first birefringent window, to reverse the orthogonal polarizations associated with the first beamlet pair and the second beamlet pair;
a second birefringent window, arranged after the second half-waveplate, to refract and shift the first beamlet pair and the second beamlet pair such that a first beamlet of the first beamlet pair and a second beamlet of the second beamlet pair form overlapping beams; and
an analyzer, arranged after the second birefringent window, to split the overlapping beams into a first output beam associated with a first intensity and a second output beam associated with a second intensity,
wherein a difference between the first intensity and the second intensity is related to a phase difference between the first input beam and the second input beam.

2. The phase detector of claim 1, wherein the first half-waveplate, the first birefringent window, the second half-waveplate, the second birefringent window, and the analyzer are arranged in a linear optical path.

3. The phase detector of claim 1, wherein the first birefringent window and the second birefringent window are made from a birefringent material comprising one or more of alpha-barium borate crystal, undoped vanadate, calcite, or rutile.

4. The phase detector of claim 1, wherein the first birefringent window and the second birefringent window refract the orthogonal polarizations at different angles to laterally shift propagation axes of the first beamlet pair and the second beamlet pair.

5. The phase detector of claim 1, wherein thicknesses and angles of the first birefringent window and the second birefringent window are based on a separation between the first input beam and the second input beam.

6. The phase detector of claim 1, wherein the analyzer comprises:
a quarter-waveplate, arranged after the second birefringent window; and
a third birefringent window, arranged after the quarter-waveplate.

7. The phase detector of claim 1, wherein the difference between the first intensity and the second intensity is approximately equal to a sine of the phase difference between the first input beam and the second input beam.

8. The phase detector of claim 1, further comprising:
a feedback loop that comprises one or more devices configured to measure the first intensity and the second intensity and to generate a control signal to modulate a phase of one or more of the first input beam or the second input beam according to the phase difference between the first input beam and the second input beam.

9. A method for phase detection to enable coherent beam combining, comprising:
receiving, by a phase detector that comprises a plurality of optical devices arranged in a linear optical path, a first input beam and a second input beam;
dividing, by the phase detector, the first input beam into a first beamlet pair associated with orthogonal polarizations and the second input beam into a second beamlet pair associated with orthogonal polarizations;
shifting, by the phase detector, the first beamlet pair and the second beamlet pair such that a first beamlet of the first beamlet pair and a second beamlet of the second beamlet pair form overlapping beams; and
splitting, by the phase detector, the overlapping beams into a first output beam associated with a first intensity and a second output beam associated with a second intensity,
wherein a difference between the first intensity and the second intensity is related to a phase difference between the first input beam and the second input beam.

10. The method of claim 9, further comprising:
providing a signal indicating the phase difference between the first input beam and the second input beam to a control system configured to modulate one or more of a first phase of the first input beam or a second phase of the second input according to the phase difference.

11. The method of claim 9, wherein the first input beam and the second input beam are received at a first half-waveplate configured to rotate a polarization of the first input beam and the second input beam to 45 degrees.

12. The method of claim 11, wherein the first input beam and the second input beam are divided into the first beamlet pair and the second beamlet pair by a first birefringent window, arranged after the first half-waveplate.

13. The method of claim 12, further comprising:
reversing, by a second half-waveplate, arranged after the first birefringent window, the orthogonal polarizations associated with the first beamlet pair and the second beamlet pair.

14. The method of claim 13, wherein the first beamlet pair and the second beamlet pair are shifted by a second birefringent window, arranged after the second half-waveplate.

15. The method of claim 14, wherein the overlapping beams are split into the first output beam and the second output beam by an analyzer that comprises:
a quarter-waveplate, arranged after the second birefringent window; and
a third birefringent window, arranged after the quarter-waveplate.

16. The method of claim 9, wherein the difference between the first intensity and the second intensity is approximately equal to a sine of the phase difference between the first input beam and the second input beam.

17. An optical system, comprising:
a laser source configured to generate a seed laser;
a division stage comprising one or more optical devices configured to divide the seed laser into a beam array that comprises a first input beam and a second input beam that co-propagate with a first polarization;
an amplification stage comprising a first amplifier to amplify the first input beam and a second amplifier to amplify the second input beam;
a combination stage comprising one or more optical devices configured to combine the amplified first input beam and the amplified second input beam to generate an output beam;
a phase detector, provided after the amplification stage, comprising:
a first half-waveplate arranged to receive the first input beam and the second input beam and to rotate the first polarization to 45 degrees;
a first birefringent window, arranged after the first half-waveplate, to divide the first input beam into a first beamlet pair associated with orthogonal polarizations and to divide the second input beam into a second beamlet pair associated with orthogonal polarizations;
a second half-waveplate, arranged after the first birefringent window, to reverse the orthogonal polarizations associated with the first beamlet pair and the second beamlet pair;
a second birefringent window, arranged after the second half-waveplate, to refract and shift the first beamlet pair and the second beamlet pair such that a first beamlet of the first beamlet pair and a second beamlet of the second beamlet pair form overlapping beams; and
an analyzer, arranged after the second birefringent window, to split the overlapping beams into a first output beam associated with a first intensity and a second output beam associated with a second intensity,
wherein a difference between the first intensity and the second intensity is related to a phase difference between the first input beam and the second input beam; and
a feedback loop that comprises one or more devices configured to measure the first intensity and the second intensity and to generate a control signal to modulate, prior to the amplification stage, a phase of one or more of the first input beam or the second input beam according to the phase difference between the first input beam and the second input beam.

18. The optical system of claim 17, wherein the first half-waveplate, the first birefringent window, the second half-waveplate, the second birefringent window, and the analyzer are arranged in a linear optical path.

19. The optical system of claim 17, wherein thicknesses and angles of the first birefringent window and the second birefringent window are based on a separation between the first input beam and the second input beam.

20. The optical system of claim 17, wherein the difference between the first intensity and the second intensity is approximately equal to a sine of the phase difference between the first input beam and the second input beam.
